(19) United States
(12) Patent Application Publication
(10) Pub. No.: US 2009/0045723 A1
(43) Pub. Date: Feb. 19, 2009

(54) APPARATUS AND METHOD FOR SYNCHRONIZING ILLUMINATION AROUND AN ORGANIC LIGHT EMITTING DISPLAY

(75) Inventor: Tomohiro Ishikawa, Evanston, IL (US)

Correspondence Address: INGRASSIA FISHER & LORENZ, P.C. (MOT), 7010 E. Cochise Road, SCOTTSDALE, AZ, 85253, US

(73) Assignee: MOTOROLA, INC., Schaumburg, IL (US)

(21) Appl. No.: 11/839,369

(22) Filed: Aug. 15, 2007

(51) Int. Cl. H01L 51/52; F21V 37/00

(52) U.S. Cl. 313/504; 362/355

(57) ABSTRACT

A diffuser (204, 504, 804, 1111) is disposed on the sides of an organic light emitting diode (OLED) display (202, 502, 802, 1112) for diffusing light (214, 218, 522, 532, 536, 814, 816) emitted from the sides of the organic layer of the OLED display (202, 502, 802, 1112). The diffused light (214, 218, 522, 532, 536, 814, 816) may be emitted forward towards the viewer of the OLED display (202, 502, 802, 1112) or backwards for highlighting, for example, a wall behind the OLED display (202, 502, 802, 1112). The intensity of the diffused light (214, 218, 522, 532, 536, 814, 816) being emitted from a portion of the diffuser (204, 504, 804, 1111) generally matches the portion of the OLED display (202, 502, 802, 1112) most adjacent to the portion of the diffuser (204, 504, 804, 1111). Because the OLED display light is diffused, the diffused light is synchronized in timing and color with the perimeter of the OLED display image itself.

### FIELD

The present invention generally relates to portable electronic devices and more particularly to an organic light emitting diode (OLED) display.

### BACKGROUND

The market for personal portable electronic devices, for example, cell phones, laptop computers, personal digital assistants (PDAs), digital cameras, and music playback devices (MP3), is very competitive. Manufacturers, distributors, service providers, and third party providers have all attempted to find features that appeal to the consumer. For example, service providers are continually looking to improve cell phone reception and access to the internet for downloading of information, music, and the like. Third party providers are constantly searching for accessories that function well with the manufacture's product. Manufacturers are constantly improving their product with each model in the hopes it will appeal to the consumer more than a competitor's product.

Visual displays are well known, including, for example, televisions, monitors, and displays used on the aforementioned portable electronic devices. Such visual displays may present images, text, data, and the like to a viewer. Factors important in displays for these products include ease of visibility, brightness, and size.

Desirable features and characteristics of the present invention will become apparent from the subsequent detailed description and the appended claims, taken in conjunction with the accompanying drawings and this background.

### BRIEF DESCRIPTION OF THE DRAWINGS

Embodiments of the present invention will hereinafter be described in conjunction with the following drawing figures, wherein like numerals denote like elements, and

FIG. 1 is cross sectional view of a known organic light emitting diode (OLED) display;

FIG. 2 is a front view of an OLED display module in accordance with a first exemplary embodiment;

FIG. 3 is cross sectional view taken along line 3-3 of the exemplary embodiment of FIG. 2;

FIG. 4 is a larger view of a portion of the exemplary embodiment of FIG. 3;

FIG. 5 is a front view of an OLED display module in accordance with a second exemplary embodiment;

FIG. 6 is cross sectional view taken along line 6-6 of the exemplary embodiment of FIG. 5;

FIG. 7 is a larger view of a portion of the exemplary embodiment of FIG. 6;

FIG. 8 is a front view of an OLED display module in accordance with a third exemplary embodiment;

FIG. 9 is cross sectional view taken along line 9-9 of the exemplary embodiment of FIG. 8;

FIG. 10 is a larger view of a portion of the exemplary embodiment of FIG. 9;

FIG. 11 is a front view of a portable electronic device including a display module in accordance with the exemplary embodiment; and

FIG. 12 is a block diagram illustrating circuitry for implementing various exemplary embodiments on the portable electronic device of FIG. 1.

### DETAILED DESCRIPTION

A material is disposed on the sides of an organic light emitting diode (OLED) display for diffusing light emitted from the sides of the organic layer of the OLED display. The diffused light may be emitted forward towards the viewer of the OLED display or backwards away from the viewer for highlighting, for example, a wall behind the OLED display. The intensity, and shade or color, of the diffused light being emitted from a portion of the diffuser generally matches the portion of the OLED display most adjacent to that portion of the diffuser. This diffusion of light around the display may reduce eyestrain of the viewer and give the impression of a larger and brighter display.

By redirecting and diffusing light emitted from the sides of an organic layer in an OLED display, the color and intensity of the diffused light is naturally synchronized with contents of the displayed images on the OLED display. Thus, instead of not reaching the viewers, this side light is employed as a synchronized illumination feature of the OLED display. A side of the OLED display is defined as the top, bottom, left side, and right side, and not the front viewing screen or the back opposed to the viewing screen.

The following detailed description is merely exemplary in nature and is not intended to limit the invention or the application and uses of the invention. Furthermore, there is no intention to be bound by any theory presented in the preceding background or the following detailed description.

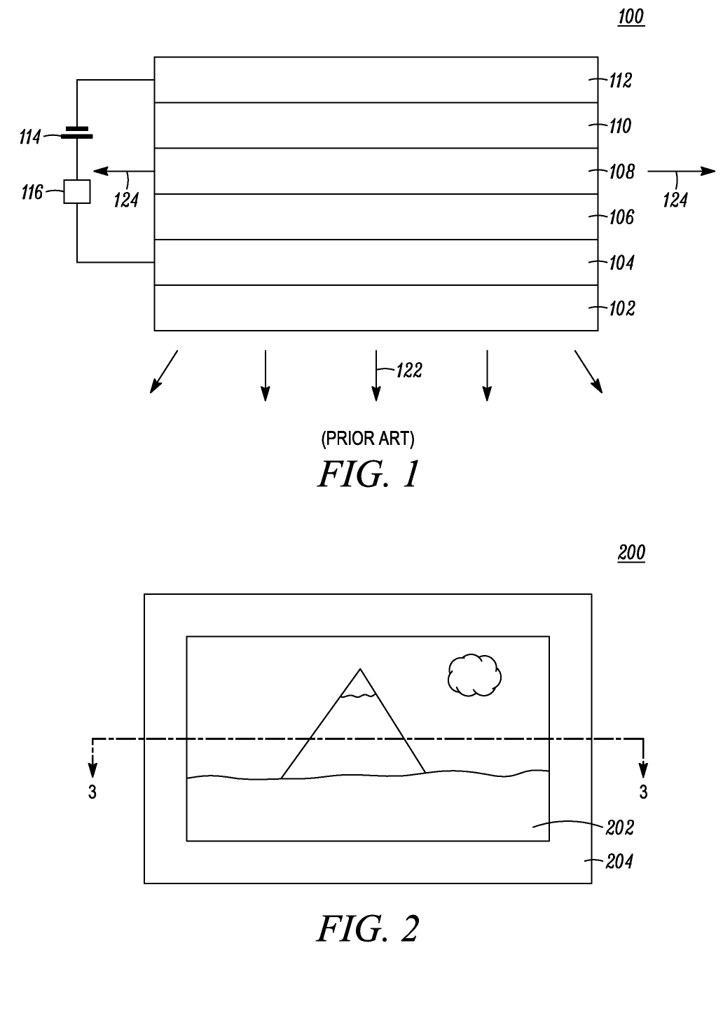

Referring to FIG. 1, a cross sectional view of a known OLED display 100 includes a first electrode 104 (anode) formed on a substrate 102. The substrate typically is formed of a transparent, sturdy, thin material such as glass, but may be a flexible polymer such as polyethylene terephthalate (PET) or polyethylene naphthalate (PEN), for example. A hole transport layer 106 is formed on the first electrode 104. The first electrode 104 and the hole transport layer 106 may be, for example, indium tin oxide (ITO) or poly-3,4-ethylenedioxthiophene (PEDOT). An organic layer 108 is an emission layer. A typical example of the emission layer is organo metallic compound such as tris (8-hydroxyquinoline) aluminum, also known as Alq3, formed on the hole transport layer 106. Note that the hole transport layer 106 could also be made of inorganic materials. An electron transport layer 110 and a second electrode 112 (cathode) are then formed over the organic layer 108. The electron transport layer 110 typically is oxydiazole derivative (OXD). The first electrode 104 is transparent while the second electrode 112, is typically metal and reflective.

In operation, a voltage from the voltage source 114 is selectively applied by switch 116 across the first and second electrodes 104, 112, causing a current of electrons to flow from the cathode to the anode. Therefore, the cathode 112 gives electrons to the electron transport layer 110 and the anode 104 withdraws electrons from the hole transport layer 106, causing the electron transport layer 110 to become negatively charged and the hole transport layer 106 to become replete with positive charged holes. Electrostatic forces bring the electrons and holes towards each other where they combine within the organic layer 108. The recombination causes a drop in the energy levels of electrons and an accompanied emission of photons. It is desired for the photons to emit through, and substantially perpendicular to, the anode 104 as indicated by the arrows 122. However, some photons are emitted parallel thereto as indicated by the arrows 124. This “sideways” emission of photons has previously been undesired since those photons do not contribute to the viewable image generated by the display 100.

Referring to FIG. 2 and in accordance with a first exemplary embodiment, a display module 200 includes a diffuser 204 disposed contiguous (adjacent as shown) to, and around the periphery of, the OLED display 202. It should be understood the diffuser 204 may be disposed on only a portion of the periphery, e.g, one side only, two sides only, portions of any side, etc. The OLED display 202 includes (not shown) a substrate, an anode, a hole transport layer, an organic layer, an electron transport layer, and a cathode as described in conjunction with FIG. 1. The image formed on the OLED display 202 can be either monochromatic or polychromatic. In this embodiment, the foreground is green grass and the background is blue sky with white clouds, with the center being a mountain. The diffuser redirects the side light from the organic layer of the OLED display 202 and produces a green glow at the bottom portion of the diffuser 204, a blue glow at the top portion of the diffuser 204, and a glow transitioning between blue and green on the right and left portions of the diffuser 204. As the image on the OLED display 202 changes, the illumination from the diffuser 204 automatically changes and is inherently synchronized in color and timing.

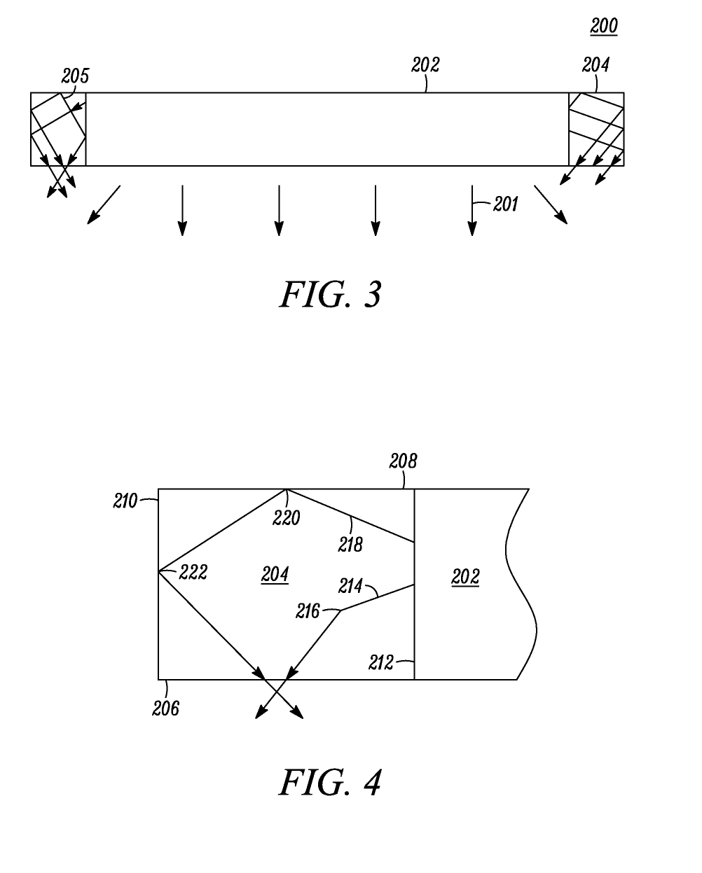

FIG. 3 is a top view of the display module 200 taken along the line 3-3 of FIG. 2 and shows the display 202 having the diffuser 204 made of polymer disposed on the sides thereof by any known fastening or attaching method. One method of fastening uses an index-matched optical adhesive that allows the light to pass freely from the OLED display 202. Alternatively, the diffuser 204 may be a sealant material for sealing the sides of the OLED display 202 with diffusion particles. The diffuser 204 has a material that diffuses light 205. To diffuse, as used herein, means to spread out, or decrease the concentration, including by reflection, redirection, or redistribution (subsequent discussion and FIG. 4 further explains how the light is diffused). The diffuser 204 material preferably includes a mixture of polymer and inorganic particles such as TiO₂. The image, represented by arrows 201 in FIG. 3, projected from the front of the OLED display 202 may have a color content or be monochromatic.

FIG. 4 is a larger view of the diffuser 204, which includes a front 206, a back 208, a outer side 210, and an inner side 212. The back 208 and outer side 210 both preferably have a reflective surface to reflect the light back within the diffuser (internal reflection). The front has a non-reflective surface. As the previously undesired light exits the side of the OLED display 202, it is diffused by the material of the diffuser 204, and redirected as appropriate by the back 208 and outer side 210 to exit the front 206 toward the viewer of the OLED display 202. For example, a beam of light 214 is diffused at point 216 and exits the front 206, and a beam of light 218 is reflected off the back 208 at point 220 and outer side 210 at point 222 to exit the front 206.

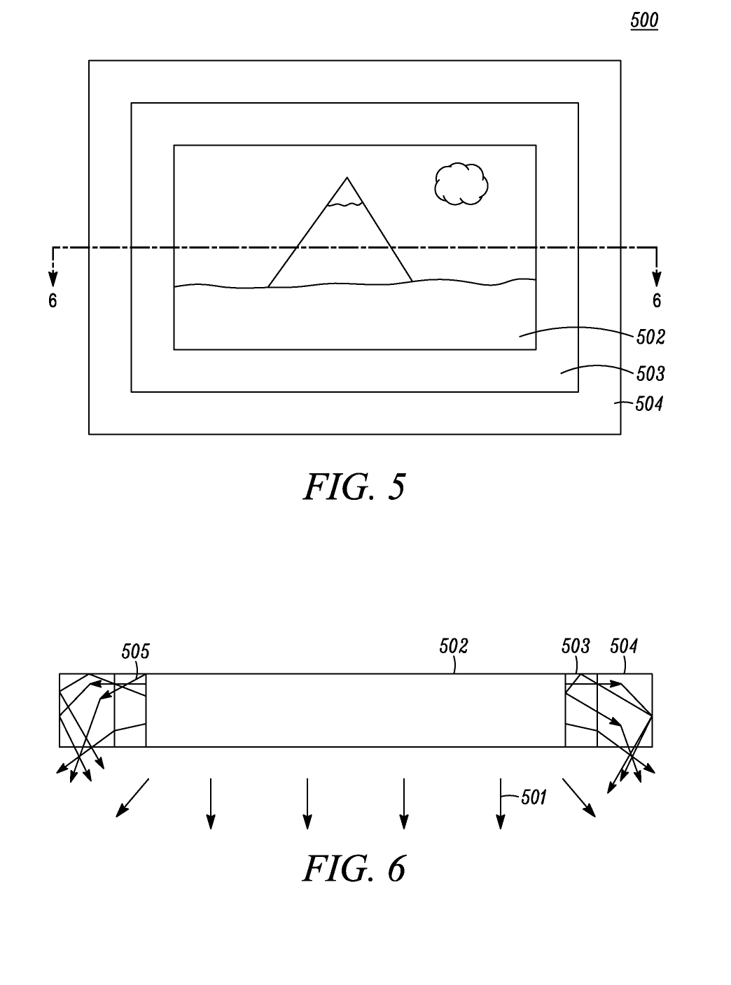

FIG. 5 is a front view, and FIG. 6 is a cross section view taken along line 6-6 of FIG. 5, of a second exemplary embodiment wherein a display module 500 displaying light 501 includes a transitional device 503 disposed between an OLED display 502 and a diffuser 504. It should be understood the diffuser 504 may be disposed on only a portion of the periphery, e.g, only on the top and bottom, a portion of the top and bottom, etc. The OLED display 502 includes (not shown) a substrate, an anode, a hole transport layer, an organic layer, an electron transport layer, and a cathode as described in conjunction with FIG. 1. The transitional device 503 is a transparent material having an index of refraction higher than 1.4 (relying on total internal reflection, or the difference in the index of reflection of air (equal to 1) and the transparent material of the transitional device 503, most material have an index of reflection higher than 1.4). The transitional device 503 directs the side light 505 from the display to the diffuser by means of total internal reflection.

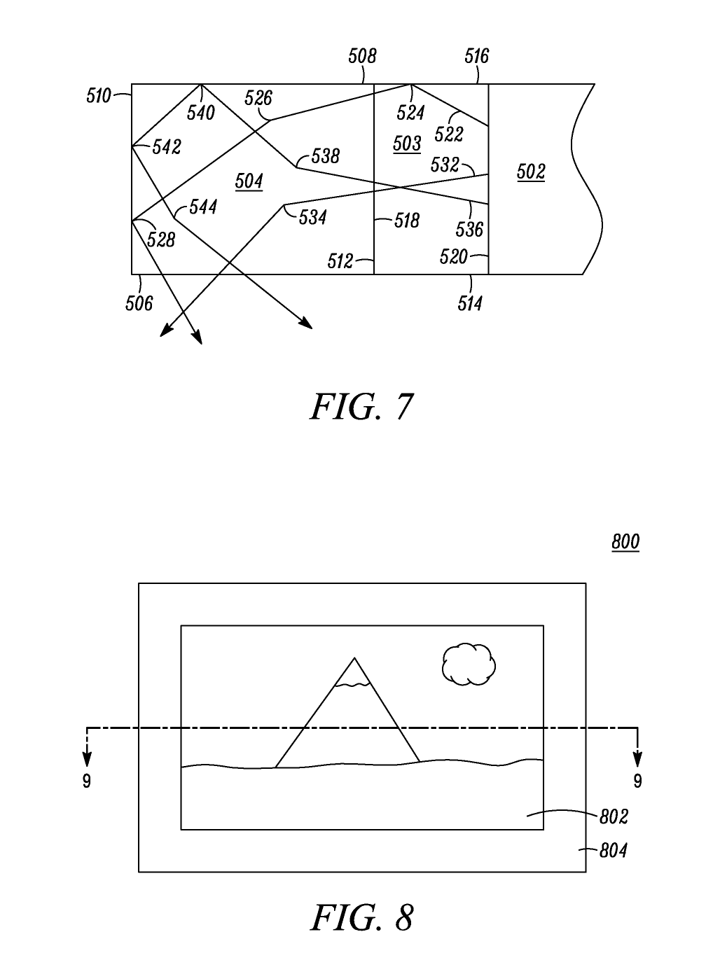

As shown in FIG. 7, the transitional device 503 includes a front 514, a back 516, an outer side 518, and an inner side 520. The light entering the inner side 520 from the OLED display 502 passes through the transitional device 503 to the diffuser 504. The transitional device 503 displaces the emission of light from the front 506 of the diffuser 504 a distance from the OLED display 502. As in the previously discussed embodiment, a diffuser 504 includes a front 506, a back 508, an outer side 510, and an inner side 512. The back 508 and outer side 510 both preferably have a reflective surface to reflect the light back within the diffuser; however, the index of refraction may sufficiently redirect the light in accordance with artistic or commercial desires. The front 506 has a non-reflective surface. As the previously undesired light exits the side of the OLED display 502, it is first directed to the diffuser 504 by the transitional device 503 and then diffused by the material of the diffuser 504, and redirected as appropriate by the back 508 and outer side 510 to exit the front 506 toward the viewer of the OLED display 502. For example, a beam of light 522 reflects off the back 516 of the transitional device 503 due to total internal reflection at point 524, is diffused at point 526, reflected off the outer side 510 of the diffuser 504 at point 528 and exits the front 506; a beam of light 532 passes through the transitional device 503, is diffused at point 534 and exits the front 506; and a beam of light 536 passes through the transitional device 503, is diffused at point 538, reflects off the back 508 at point 540, reflects off the outer side 510 at point 542, is diffused at point 544, and exits the front 506.

The first and second embodiments provide forward projecting illumination (like an aura) around an OLED display. A third embodiment can provide rear-projecting illumination around an OLED display. When a portion of the OLED display has a shade or color, the portion of the diffuser immediately adjacent will provide an appearance having the same shade or color. Therefore, the diffuser can provide an appearance with multiple shades or colors synchronized with the periphery of a multicolor image on the display.

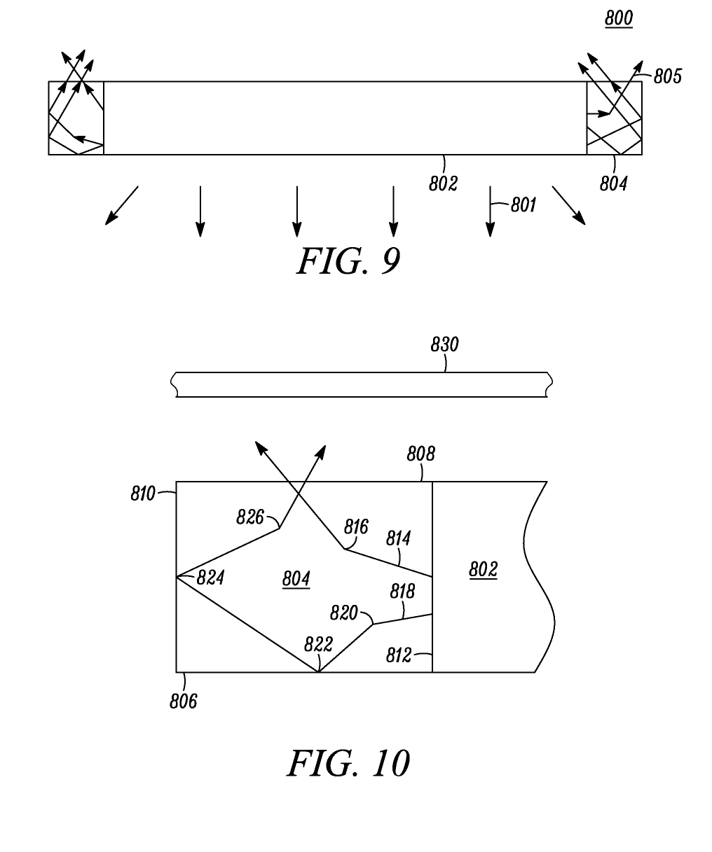

Referring to FIG. 8 and in accordance with a third exemplary embodiment, an OLED display module 800 includes a diffuser 804 disposed contiguous (adjacent as shown) to, and around the periphery of, an OLED display 802. It should be understood the diffuser 804 may be disposed on only a portion of the periphery, e.g, a right side and/or the top. The OLED display 802 includes (not shown) a substrate, an anode, a hole transport layer, an organic layer, an electron transport layer, and a cathode as described in conjunction with FIG. 1. FIG. 9 is a cross-sectional view of the OLED display module 800 taken along the line 9-9 of FIG. 8 and shows the OLED display 802 having the diffuser 804 disposed on the sides thereof. One method of fastening is an index-matched optical adhesive that allows the light to pass freely from the OLED display 802. Alternatively, the diffuser 804 may be a sealant material for sealing the sides of the OLED display 802. The diffuser 804 has a material that diffuses light 805 emitted from the sides of the organic layer of the OLED display 802. The diffuser 804 material preferably includes a mixture of polymer and inorganic particle such as TiO₂. The image (light 801) on the OLED display 802 may have a color content or be monochromatic.

FIG. 10 is a larger view of the diffuser 804, which includes a front 806, a back 808, a outer side 810, and an inner side 812. In this embodiment, the front 806 and outer side 810 both preferably have a reflective surface. As the previously undesired light exits the side of the OLED display 802, it is diffused by the material of the diffuser 804, and redirected as appropriate by the front 806 and outer side 810 to exit the back 808 away from the viewer of the OLED display 802 and toward a surface 830 such as a wall or other external surface behind the OLED display 802. For example, a beam of light 814 is diffused at point 816 and exits the back 808, and beam of light 818 is diffused at point 820, reflected off the front 806 at point 822 and outer side 810 at point 824, and diffused at point 826 to exit the back 808. The diffused light 814, 818 exiting the back 808 may then strike a surface 830, for example a wall, to illuminate the area directly behind the OLED display module 800. Thus, a glow or aura is achieved indirectly rather than directly as shown in FIGS. 2-8.

For each of the three exemplary embodiments described herein, for a portion of the display (202, 502, 802) perimeter that is very bright, for example, blue sky or bright clouds, the light (214, 218, 522, 532, 536, 814, 818) emitted sideways tends to reach a section of the diffuser (204, 504, 804) adjacent to that portion; however, some of that diffused bright light (214, 218, 522, 532, 536, 814, 818) will migrate in the diffuser (204, 504, 804) to an area of the diffuser (204, 504, 804) that perhaps is not adjacent to a bright portion on the display (202, 502, 802). The diffused light (214, 218, 522, 532, 536, 814, 818) emitting from the diffuser (204, 504, 804) will go from bright in one portion of the diffuser (204, 504, 804) to less bright to an adjacent portion of the diffuser (204, 504, 804), in gray scales in an analogue manner. For a color display, the intensity of the colors in the diffuser (204, 504, 804) would also migrate, and generally fades as the distance from the display (202, 502, 802) perimeter increases.

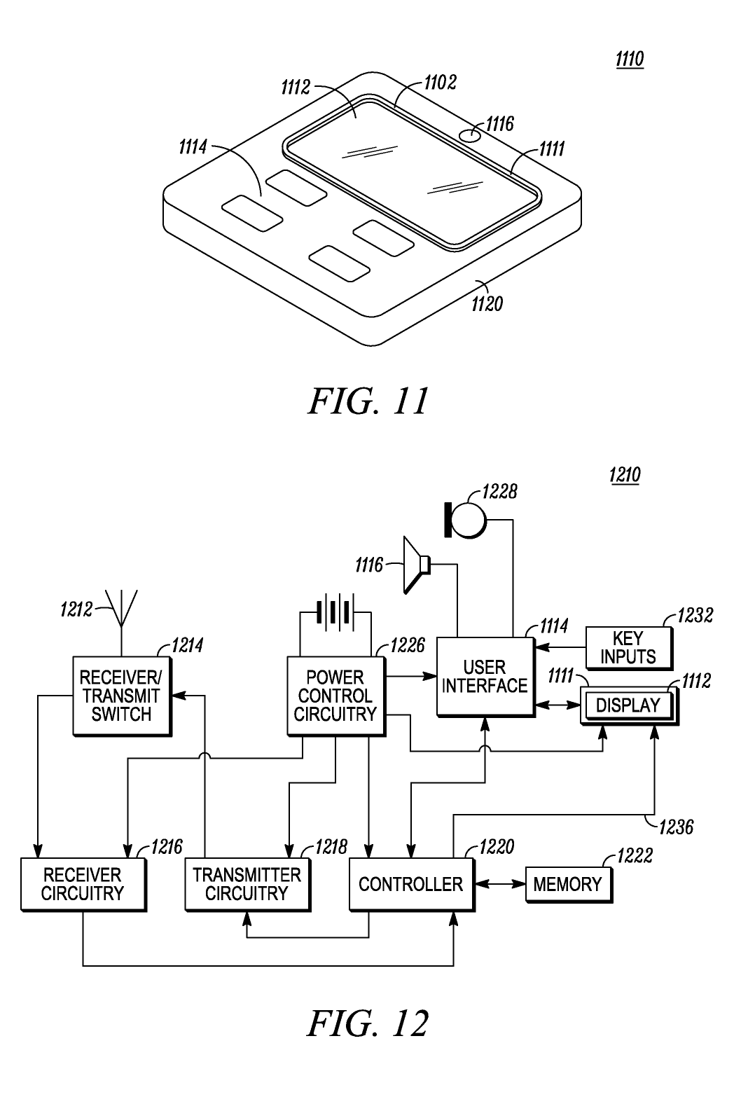

Referring to FIG. 11, an electronic device 1110 has an OLED display 1112, a user interface 1114, and a speaker 1116 encased in a housing 1120. In accordance with an exemplary embodiment, a diffuser 1111 is disposed adjacent the OLED display 1112. Some electronic devices 1110, e.g., a cell phone, may include other elements such as an antenna, a microphone, and a camera (none shown). Furthermore, while the preferred exemplary embodiment of an electronic device is described as a mobile communication device, for example, cellular telephones, messaging devices, and mobile data terminals, other embodiments are envisioned, for example, flat panel advertising screens, personal digital assistants (PDAs), computer monitors, gaming devices, video gaming devices, cameras, and DVD players.

Referring to FIG. 12, a block diagram of an electronic device 1210 such as a cellular phone, in accordance with the exemplary embodiment is depicted. Though the exemplary embodiment is a cellular phone, the display described herein may be used with any electronic device in which information, colors, or patterns are to be presented through light emission. The portable electronic device 1210 includes an antenna 1212 for receiving and transmitting radio frequency (RF) signals. A receive/transmit switch 1214 selectively couples the antenna 1212 to receiver circuitry 1216 and transmitter circuitry 1218 in a manner familiar to those skilled in the art. The receiver circuitry 1216 demodulates and decodes the RF signals to derive information therefrom and is coupled to a controller 1220 for providing the decoded information for utilization in accordance with the function(s) of the portable electronic device 1210. The controller 1220 also provides information to the transmitter circuitry 1218 for encoding and modulating information into RF signals for transmission from the antenna 1212. As is well-known in the art, the controller 1220 is typically coupled to a memory device 1222 and a user interface 1114 to perform the functions of the portable electronic device 1210. Power control circuitry 1226 is coupled to the components of the portable communication device 1210, such as the controller 1220, the receiver circuitry 1216, the transmitter circuitry 1218 and/or the user interface 1114, to provide appropriate operational voltage and current to those components. The user interface 1114 includes a microphone 1228, a speaker 1116 and one or more key inputs 1232, including a keypad. The user interface 1114 also includes an OLED display 1112 and diffuser 1111, which could receive touch screen inputs. The display 1112 is coupled to the controller 1220 by the conductor 1236 for selective application of voltages in some of the exemplary embodiments described above.

When a picture is presented on the display 1112, the light emitted from the side of the display 1112 will be diffused and projected from the diffuser 1111. This projection gives the viewer an impression of a larger image.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. A display comprising:
an organic light emitting diode (OLED) display having a viewable front and at least one side having light emitted therefrom; and
a diffuser disposed contiguous to at least a portion of the at least one side and capable of receiving the light from the at least one side and for providing diffused light contiguous to the OLED display.

2. The display of claim 1 further comprising a transitional area disposed between the OLED display and the diffuser for displacing the diffused light from the display.

3. The display of claim 1 wherein the diffuser comprises a polymer.

4. The display of claim 1 wherein the OLED display emits light from its periphery and the diffuser is disposed contiguous to the periphery.

5. The display of claim 1 wherein the diffuser comprises:
a first portion having an internal reflective surface; and
second portion having an internal non-reflective surface.

6. The display of claim 5 wherein the first portion comprises:
a side surface disposed by the OLED display, and
a back surface; and
the second portion comprises:
a front surface.

7. The display of claim 5 wherein the first portion comprises:
a side surface disposed by the OLED display, and
a front surface; and
the second portion comprises:
a back surface.

8. The display of claim 1 wherein the diffuser provides the diffused light around the entire perimeter of the OLED display.

9. The display of claim 1 wherein the diffused light is provided in shades as determined by a portion of the OLED display immediately adjacent thereto.

10. The display of claim 1 wherein the diffused light is provided in colors as determined by a portion of the OLED display immediately adjacent thereto.

11. The display of claim 1 wherein the OLED display comprises:
an organic layer disposed between an electron transport layer and a hole transport layer.

12. A method of illuminating an area contiguous to an organic light emitting diode (OLED) display, wherein the OLED display emits light from a front in a forward direction for viewing and emits light from at least one side, comprising:
diffusing the light by a diffuser disposed contiguous to at least a portion of the at least one side to illuminate the area contiguous to the OLED display.

13. The method of claim 12 further comprising:
displacing the illuminated area from the OLED display.

14. The method of claim 12 wherein the diffusing comprises:
diffusing the light with a polymer material.

15. The method of claim 12 further comprising:
emitting the light from the diffuser in the forward direction.

16. The method of claim 12 further comprising:
emitting the light from the diffuser in a backward direction.

17. The method of claim 12 further comprising:
reflecting the light traveling in a backward direction within the diffuser and emitting diffused light in the forward direction.

18. The method of claim 12 further comprising:
reflecting the light traveling in the forward direction within the diffuser and emitting diffused light in a backward direction.
